(19) United States
(12) Patent Application Publication
(10) Pub. No.: US 2022/0148817 A1
(43) Pub. Date: May 12, 2022

(54) PHOTOELECTRODE WITH INDEPENDENT SEPARATE STRUCTURES OF ELECTROCHROMIC LAYER AND SENSITIZED LIGHT-ABSORBING LAYER, AND PHOTOELECTROCHROMIC DEVICE

(71) Applicant: National Taiwan University of Science and Technology, Taipei (TW)

(72) Inventors: Min-Hsin Yeh, New Taipei City (TW); Chao-Yuan Cheng, Taipei City (TW); Yu-Jou Chiang, Taipei City (TW)

(73) Assignee: National Taiwan University of Science and Technology, Taipei (TW)

(21) Appl. No.: 17/123,154

(22) Filed: Dec. 16, 2020

(30) Foreign Application Priority Data
Nov. 11, 2020 (TW) 109139286

(51) Int. Cl. H01G 9/20; H01L 51/42; H01L 51/44; G02F 1/155; G02F 1/1516

(52) U.S. Cl. CPC H01G 9/209; H01G 9/2059; H01L 51/4253; G02F 2001/1555; H01L 51/447; G02F 1/155; G02F 1/1516; H01L 51/442

(57) ABSTRACT

A photoelectrode with independent separate structures of an electrochromic layer and a sensitized light-absorbing layer is provided, which includes a first transparent conductive substrate, a first electrochromic layer, and a sensitized light-absorbing layer. The first electrochromic layer and the sensitized light-absorbing layer are disposed on a surface of the first transparent conductive substrate and are adjacent to each other.

### CROSS-REFERENCE TO RELATED APPLICATION

This application claims the priority benefit of Taiwan application serial no. 109139286, filed on Nov. 11, 2020. The entirety of the above-mentioned patent application is hereby incorporated by reference herein and made a part of this specification.

### BACKGROUND

### Technical Field

The disclosure relates to a photoelectrochromic device (PECD) technique, and in particular, to a photoelectrode with independent separate structures of an electrochromic layer and a sensitized light-absorbing layer, and a photoelectrochromic device having fast coloring/bleaching characteristics.

### Description of Related Art

The current photoelectrochromic device (PECD) systems are limited by the transmittance of the photoactive layer, the selection of the electrochromic material, the type and concentration of the electrolyte, and the differences in structure. Therefore, high optical contrast and fast response time as in conventional electrochromic devices cannot be achieved.

To address the above issues, a separated type PECD (S-PECD) in which the electrochromic layer and the sensitized light-absorbing layer are respectively fixed on the surfaces of the photoelectrode and the counter electrode, and a combined type PECD (C-PECD) in which the electrochromic layer and the sensitized light-absorbing layer are combined together on the surface of the photoelectrode have been developed. Compared with the separated type PECD, the combined type PECD exhibits better coloring/bleaching response time because of a different operation mechanism. However, due to the high temperature process for preparing the photoelectrode, the current combined type PECD studies use inorganic electrochromic materials. Although such materials have the advantage of high stability, due to the low coloration efficiency (<100 cm² C⁻¹) and high electron transfer resistance, the response time of the combined type PECD generally falls in the range of hundreds of seconds, and thus the original advantage of this structure is lost.

On the other hand, the separated type PECD is the most complete structure currently known and developed. This structure is characterized by the dual-function electrode of inorganic composite material/conductive polymer on the counter electrode. By improving the photovoltaic performance of the PECD, the optical contrast is increased and the coloring/bleaching response time is shortened. However, when the catalytic ability on the counter electrode increases, it means that the electrode will tend to transfer the electrons of the colored electrochromic material to the electrode surface to carry out the I₃⁻ reduction reaction, which results in a decrease in the degree of the reduced state (lighter colored state) and affects the overall optical contrast of the PECD.

### SUMMARY

The disclosure provides a photoelectrode with independent separate structures of an electrochromic layer and a sensitized light-absorbing layer, which can reduce electron transfer resistance and increase the selectivity of the electrochromic layer.

The disclosure also provides a photoelectrochromic device, which exhibits fast coloring/bleaching characteristics and solves the issue of insufficient optical contrast of a dual-function electrode.

A photoelectrode with independent separate structures of an electrochromic layer and a sensitized light-absorbing layer according to the disclosure includes a first transparent conductive substrate, a first electrochromic layer, and a sensitized light-absorbing layer. The first electrochromic layer and the sensitized light-absorbing layer are disposed on a surface of the first transparent conductive substrate and are adjacent to each other.

In an embodiment of the disclosure, a distance between the first electrochromic layer and the sensitized light-absorbing layer is 0.05 cm or less.

In an embodiment of the disclosure, the first electrochromic layer and the sensitized light-absorbing layer are in direct contact with each other and do not overlap with each other.

A photoelectrochromic device according to the disclosure includes the above photoelectrode, a counter electrode plate, and an electrolyte. The photoelectrode includes the first electrochromic layer and the sensitized light-absorbing layer adjacent to each other. The counter electrode plate includes a second transparent conductive substrate, and a second electrochromic layer or a metal layer disposed on a surface of the second transparent conductive substrate. The electrolyte is located between the photoelectrode and the counter electrode plate.

In another embodiment of the disclosure, a material of the first electrochromic layer and a material of the second electrochromic layer each independently include a transition metal oxide, a metal cyanide, an organic small molecule compound, or a conductive polymer.

In another embodiment of the disclosure, a material of the first electrochromic layer and a material of the second electrochromic layer each independently include poly(3,4-ethylenedioxythiophene) (PEDOT), poly(hydroxymethyl 3,4-ethylenedioxythiophene) (PEDOT-MeOH), or Prussian blue (PB).

In another embodiment of the disclosure, a material of the metal layer includes platinum (Pt).

In another embodiment of the disclosure, a ratio of an area of the first electrochromic layer to an area of the sensitized light-absorbing layer is between 1 and 4.

Based on the above, in the disclosure, with the specific design of the sensitized light-absorbing layer and the electrochromic layer, the manufacturing processes of the sensitized light-absorbing layer and the electrochromic layer can be separated, so that the energy supply terminal and the electrochromic material in the PECD can be provide on the same photoelectrode. Therefore, the selection of materials can be more diverse, and conductive polymers which are less resistant to high temperature processes can be used as the material of the electrochromic layer, so as to significantly improve the slow response time of using an oxide as the electrochromic material in the conventional art. Moreover, in addition to using metal and similar materials as the counter electrode, a dual-function counter electrode having a high transmittance can also be used to enhance the performance of the PECD, that is, the electrochromic material is used as the counter electrode. In the disclosure, with the operation mechanism of the structure and the diversity of the electrochromic layer material, the response time of the device exhibits a tendency of significant shortening as compared with the conventional PECD. In addition, the disclosure exhibits a high photocoloration efficiency (PhCE), which reduces the energy requirements, and it has been experimentally confirmed that the photoelectrochromic device of the disclosure exhibits a fast response time and can complete coloration and bleaching and achieve balance within seconds.

To make the aforementioned more comprehensible, several embodiments accompanied with drawings are described in detail as follows.

### BRIEF DESCRIPTION OF THE DRAWINGS

FIG. 1 is a schematic cross-sectional view of a photoelectrochromic device according to a first embodiment of the disclosure.

FIG. 2A and FIG. 2B respectively show schematic enlarged views of part II in FIG. 1 in different examples.

FIG. 3 is a schematic cross-sectional view of a photoelectrochromic device according to a second embodiment of the disclosure.

FIG. 4 is a schematic view of a device for testing a response time and a photocoloration efficiency.

FIG. 5 is a curve chart showing optical performance changes of Preparative Example 1 and Comparative Example.

FIG. 6 is a curve chart showing a photocoloration efficiency of Preparative Example 1 and Comparative Example.

### DESCRIPTION OF THE EMBODIMENTS

The accompanying drawings in the following embodiments are intended to describe the embodiments of the disclosure more completely, but the disclosure may still be implemented in many different forms and is not limited to the described embodiments. In addition, the relative thickness, distance, and position of each region or film layer may have been reduced or enlarged to make the difference clear, so the sizes in the drawings may not have been drawn to scale. In addition, similar or identical reference numerals are used in the drawings to indicate similar or identical parts or regions.

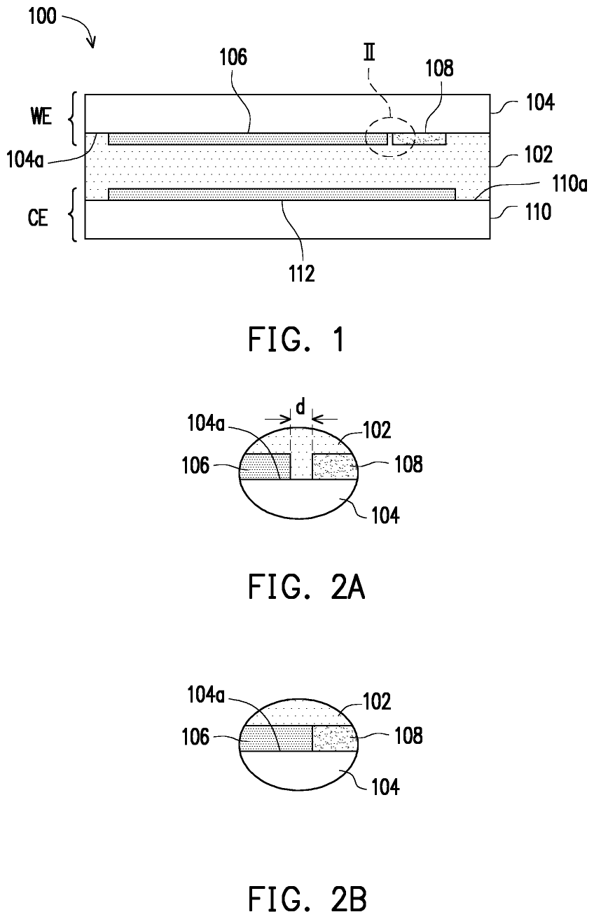

FIG. 1 is a schematic cross-sectional view of a photoelectrochromic device according to a first embodiment of the disclosure.

Referring to FIG. 1, a photoelectrochromic device 100 of the first embodiment includes a photoelectrode (or referred to as a working electrode) WE, a counter electrode plate CE, and an electrolyte 102. The photoelectrode WE includes a first transparent conductive substrate 104 and a first electrochromic layer 106 and a sensitized light-absorbing layer 108 which are disposed on a surface 104a of the first transparent conductive substrate 104 and are adjacent to each other.

In an embodiment, the material of the first electrochromic layer 106 may include a transition metal oxide, a metal cyanide, an organic small molecule compound, or a conductive polymer. The transition metal oxide may include, but is not limited to: tungsten oxide (WO₃), molybdenum trioxide (MoO₃), titanium oxide (TiO₂), tantalum oxide (Ta₂O₅), niobium oxide (NbO), nickel oxide (NiO), vanadium oxide (V₂O₅), chromic oxide (CrO₃), cobalt oxide (CoO), iridium oxide (IrO₂), or rhodium oxide (Rh₂O₃). The metal cyanide may include, but is not limited to: Prussian blue (PB), iron cobalt cyanide, ruthenium ferrocyanide, nickel ferrocyanide, and the like. The organic small molecule compound may include, but is not limited to: viologen, methyl viologen, or heptyl viologen. The conductive polymer may include, but is not limited to: polypyrrole (PPy), poly(3-methyl thiophene) (PMeT), polyaniline (PANI), poly(3,4-ethylenedioxythiophene) (PEDOT), poly(hydroxymethyl 3,4-ethylenedioxythiophene) (PEDOT-MeOH), poly(3,4-ethylenedioxythiophene)-poly (styrenesulfonate) (PEDOT-PSS), poly(2,2-dimethyl-3,4-propylenedioxythiophene) (PProdot-Me2), or poly(2,2-diethyl-3,4-propylenedioxythiophene) (PProdot-Et2). From the viewpoint of shortening the response time, the material of the first electrochromic layer 106 may be poly(3,4-ethylenedioxythiophene) (PEDOT), poly(hydroxymethyl 3,4-ethylenedioxythiophene) (PEDOT-MeOH), or Prussian blue (PB), preferably PEDOT-MeOH. The sensitized light-absorbing layer 108 may include a photosensitized dye layer, such as a TiO₂ layer absorbed with a dye. In this embodiment, a distance d between the first electrochromic layer 106 and the sensitized light-absorbing layer 108 may be 0.05 cm or less (see FIG. 2A), and the distance d is, for example, 0.04 cm or less, 0.03 cm or less, 0.02 cm or less, 0.01 cm or less, and so on.

However, the disclosure is not limited thereto. In another embodiment, the first electrochromic layer 106 and the sensitized light-absorbing layer 108 are in direct contact with each other and do not overlap with each other (see FIG. 2B). In other words, it is also possible that the distance between the first electrochromic layer 106 and the sensitized light-absorbing layer 108 is 0. In an embodiment, the ratio of the area of the first electrochromic layer 106 to the area of the sensitized light-absorbing layer 108 may be between 1 and 4. Since FIG. 1 shows the cross-section of the device, although the area of the first electrochromic layer 106 and the area of the sensitized light-absorbing layer 108 are not directly shown, it should be understood that the ratio between the areas of the first electrochromic layer 106 and the sensitized light-absorbing layer 108 formed on the surface 104a of the first transparent conductive substrate 104 may be adjusted based on the shapes (e.g., a rectangle, a circle, a polygon, etc.) of the first electrochromic layer 106 and the sensitized light-absorbing layer 108 while taking into account the functions of generating power and displaying the color change region.

Referring to FIG. 1 again, the counter electrode plate CE of the photoelectrochromic device 100 includes a second transparent conductive substrate 110 and a second electrochromic layer 112 disposed on a surface 110a of the second transparent conductive substrate 110. In an embodiment, the material of the second electrochromic layer 112 each independently includes a transition metal oxide, a metal cyanide, an organic small molecule compound, or a conductive polymer, and reference may be made to the materials of the first electrochromic layer 106 as described above. From the viewpoint of shortening the response time, the material of the second electrochromic layer may include, for example, PEDOT, PEDOT-MeOH, or Prussian blue (PB), preferably PEDOT-MeOH. The electrolyte 102 is located between the photoelectrode WE and the counter electrode plate CE, and the electrolyte 102 is preferably an electrolytic solution.

In this embodiment, since the first electrochromic layer 106 and the sensitized light-absorbing layer 108 are separated (not overlapped), there is no need to be concerned about the temperature resistance of the electrochromic material and prevent the cathodic coloring material (first electrochromic layer 106) from being damaged by the high temperature calcination process when manufacturing the sensitized light-absorbing layer 108. Therefore, in addition to the high temperature resistant transition metal oxide, the organic small molecular compound or the conductive polymer which has a short response time may also be used as the electrochromic material. In other words, first, the sensitized light-absorbing layer 108 may be fired and formed at a high temperature on the surface 104a of the first transparent conductive substrate 104, and then the first electrochromic layer 106 may be formed at a lower temperature. Moreover, the second electrochromic layer 112 of the counter electrode plate CE also has the dual functions of simultaneously changing color and catalyzing the negative ions of the electrolytic solution (electrolyte 102). Even if the transition metal oxide is used as the material of the first electrochromic layer 106, since the first electrochromic layer 106 and the sensitized light-absorbing layer 108 do not overlap with each other, the light irradiated to the sensitized light-absorbing layer 108 does not pass through the first electrochromic layer 106, which can increase the light absorption of the sensitized light-absorbing layer 108 and thereby increase the photoelectric conversion efficiency.

The operation mechanism of the photoelectrochromic device 100 will be described below, and an electrolytic solution containing LiI and I₂ is used as the electrolyte 102 as an example. First, in the case of open circuit/illumination, the dye molecules (S) in the sensitized light-absorbing layer 108 receive the photon energy and transform from the ground state (S⁰) to the excited state (S*). The dye in the excited state injects electrons into the semiconductor nanoparticles in the sensitized light-absorbing layer 108, so that the dye molecules are oxidized (S⁺), the oxidized dye molecules react with the iodide ions (I⁻) in the electrolyte 102 and return to the ground state, and the iodide ions are oxidized to triiodide ions (I₃⁻). If the first electrochromic layer 106 located next to the sensitized light-absorbing layer 108 is a reduction coloring material, it will receive the electrons from the dye molecules and undergo a reduction reaction. At this time, the lithium ions in the electrolyte 102 play the role of balancing the charge and migrate into the first electrochromic layer 106 to transform it from a bleached state to a colored state. In the case of short circuit/dark, the first electrochromic layer 106 in the colored state is oxidized and bleached by the electrolyte 102 due to the diffusion effect. In addition, with the ability to catalyze I₃⁻ reduction, the second electrochromic layer 112 on the CE side accelerates the bleaching process of the first electrochromic layer 106. Analogously, if the first electrochromic layer 106 located next to the sensitized light-absorbing layer 108 is an oxidization coloring material (e.g., using a PB film as the first electrochromic layer and a PEDOT-MeOH film as the second electrochromic layer), the operation of the bleaching process is as follows. In the case of illumination/open circuit (I/OC), the dye molecules (S) in the photoelectrode receive the photon energy and transform from the ground state (S⁰) to the excited state (S*), and the dye in the excited state injects electrons into the semiconductor nanoparticles, so that the dye molecules are oxidized (S⁺), the oxidized dye molecules react with I⁻ and return to the ground state, and I⁻ is oxidized to I₃⁻. At this time, the PB in the photoelectrode receives the electrons excited by the dye molecules and undergoes a reduction reaction to bleach, and Li⁺ is doped on the PB film to balance the charge. At the same time, the PEDOT-MeOH film on the counter electrode is oxidized by I₃⁻ in the electrolytic solution and turns into the bleached state, and ClO₄⁻ is doped on the PEDOT-MeOH film to balance the charge. The operation of the coloring process is as follows. In the case of illumination/short circuit (I/SC), the dye molecules (S) in the photoelectrode receive the photon energy and transform from the ground state (S⁰) to the excited state (S*), and the dye in the excited state injects electrons into the semiconductor nanoparticles, so that the dye molecules are oxidized (S⁺), the oxidized dye molecules react with I⁻ and return to the ground state, and I⁻ is oxidized to I₃⁻. Due to the short circuit, there is no bias between the two electrodes, so that the PB film in the reduced state in the photoelectrode is quickly oxidized by I₃⁻ in the electrolytic solution, Li⁺ migrates out of the PB film to balance the charge, and most of the oxidation reaction of the PB is catalyzed by the PEDOT-MeOH on the counter electrode. At the same time, the electrons generated by the photoelectrode are transferred to the counter electrode via an external circuit, so that the PEDOT-MeOH undergoes a reduction reaction and is colored. At this time, ClO₄⁻ migrates out of the PEDOT-MeOH film to balance the charge.

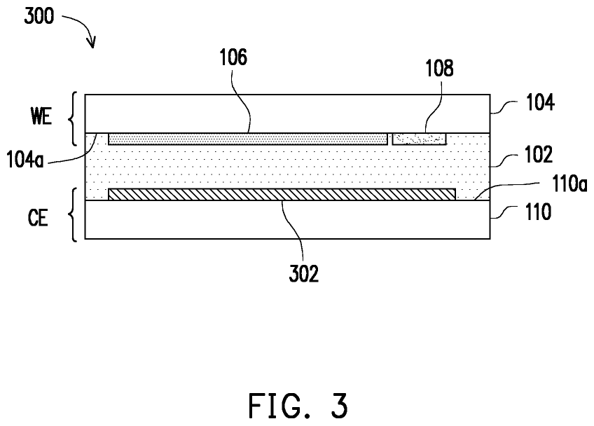

FIG. 3 is a schematic cross-sectional view of a photoelectrochromic device according to a second embodiment of the disclosure, in which the reference numerals of the first embodiment are used to indicate the same or similar components, and reference may be made to the above relevant contents for descriptions of the same components, which will not be repeated herein.

Referring to FIG. 3, the difference between a photoelectrochromic device 300 of this embodiment and the first embodiment lies in the counter electrode plate CE. A metal layer 302 is disposed on the surface 110a of the second transparent conductive substrate 110, so that the current density can be significantly increased. Specifically, the material of the metal layer 300 may be platinum (Pt), for example.

Experiments will be described below to verify the effect of the disclosure, but the disclosure is not limited to the following content.

### PREPARATIVE EXAMPLE 1

### WE and CE are Both PEDOT-MeOH

1. Preparation of Photoelectrode (WE)

1-1. Preparation of Sensitized Light-Absorbing Layer

The sensitized light-absorbing layer included three TiO₂ layers in total, including a contact layer, a transmission layer, and a scattering layer. The contact layer TiO₂ was prepared by mixing titanium tetraisopropoxide (TTIP) and 2-methoxyethanol at a weight ratio of 1:3. The transmission layer TiO₂ was purchased from Solaronix. The synthesis steps of the scattering layer TiO₂ are as follows. First, TTIP (0.5 M) and a nitric acid aqueous solution (0.1 M) were mixed and uniformly stirred at 88° C. for 8 hours, and then heated to 240° C. for 12 hours in a hydrothermal kettle. After the reaction was completed, the TiO₂ slurry in the hydrothermal kettle contained 8% by weight of TiO₂ nanoparticles. In the previously synthesized TiO₂ slurry, 25% by weight of polyethylene glycol (PEG) (relative to the TiO₂ nanoparticles) and 100% by weight of model ST-41 anatase TiO₂ (relative to the TiO₂ nanoparticles) of Ishihara Sangyo Kaisha ltd were added to synthesize a TiO₂ colloid for the scattering layer.

After preparing the above three-layer TiO₂ solution and colloid, the contact layer TiO₂ was coated on the surface of a 2.0 cm×4.0 cm FTO conductive glass by spin coating at a parameter of 3000 rpm for 30 seconds, and the coating area was 1.0 cm×2.0 cm. The transmission layer TiO₂ and the scattering layer TiO₂ were both coated by a doctor blade, and the coating area was 1.0 cm×0.25 cm. The coating sequence was the contact layer, the transmission layer, and the scattering layer, and after coating, each layer needed to be sintered to 500° C. for 30 minutes. Finally, the sintered TiO₂ electrode was soaked in N719 dye for 24 hours to complete the preparation of the sensitized light-absorbing layer.

1-2. Preparation of First Electrochromic Layer

EDOT-MeOH (0.01 M) and LiClO₄ (0.1 M) were dissolved in an acetonitrile (ACN) solvent to form a plating solution.

A working area of 1.0 cm×1.0 cm was enclosed by an epoxy tape at a distance of 0.05 cm from the edge of the sensitized light-absorbing layer, and then the EDOT-MeOH monomer in the above plating solution was polymerized on the surface of the FTO conductive glass at a constant potential by a constant potential deposition method. The parameter of the constant potential method was 1.2 V and the power was limited to 13 mC. Finally, the prepared PEDOT-MeOH (first electrochromic layer) was rinsed with ACN to wash away the remaining plating solution on the surface, and the surface was blown and dried with nitrogen.

2. Preparation of Counter Electrode Plate (CE)

EDOT-MeOH (0.01 M) and LiClO₄ (0.1 M) were dissolved in an acetonitrile (ACN) solvent to form a plating solution.

A working area of 1 cm×1.3 cm was enclosed by an epoxy tape on the surface of an ITO conductive glass of 2.0 cm×4.0 cm, and then the EDOT-MeOH monomer in the above plating solution was polymerized on the surface of the ITO conductive glass at a constant potential by a constant potential deposition method. The parameter of the constant potential method was 1.2 V and the power was limited to 13 mC. Finally, the prepared PEDOT-MeOH (second electrochromic layer) was rinsed with ACN to wash away the remaining plating solution on the surface, and the surface was blown and dried with nitrogen.

3. Packaging of Photoelectrochromic Device

The periphery of the counter electrode plate (CE) was encapsulated with Surlyn® as the thickness control layer and the packaging material, then the photoelectrode (WE) and the counter electrode plate (CE) were combined by a binder clip, and finally the Surlyn® between the two electrode plates was melted by hot pressing. Then, the required electrolytic solution was injected into the corner holes with a 5 mL syringe, and a transparent tape was attached thereto to complete the package. The formulation of the electrolytic solution was respectively a PC solvent containing LiI (0.5 M) and I₂ (0.001 M) or a PC solvent containing LiI (0.5 M) and I₂ (0.005 M).

### COMPARATIVE EXAMPLE

1. Preparation of Photoelectrode (WE) (Without First Electrochromic Layer)

1-1. Preparation of Sensitized Light-Absorbing Layer: Same as Preparative Example 1.

2. Preparation of Counter Electrode Plate (CE): Same as Preparative Example 1.

3. Packaging of Photoelectrochromic Device: Same as Preparative Example 1.

### PREPARATIVE EXAMPLE 2

### WE is PB and CE is PEDOT-MeOH

1. Preparation of Photoelectrode (WE)

1-1. Preparation of Sensitized Light-Absorbing Layer: Same as Preparative Example 1.

1-2. Synthesis of Nano-Prussian Blue (PB) Particles

3.23 g of Fe(NO₃)₃.9H₂O and 2.90 g of Na₄Fe(CN)₆.10H₂O were mixed in 45 mL of pure water and shaken well. The mixed solution was centrifuged in a centrifuge at 4000 rpm for 30 minutes, the centrifuged precipitate was centrifuged with pure water at 4000 rpm for 5 minutes six times, and 0.542 g of Na₄Fe(CN)₆.10H₂O and 10 mL of pure water were added to the centrifuged precipitate and stirred for one week. The stirred solution was centrifuged at 3000 rpm for 15 minutes, then the centrifuged clarified liquid was subjected to a rotary concentration process to obtain the PB powder, and finally the powder was dried under vacuum for one day.

1-3. Preparation of First Electrochromic Layer

Before the preparation, an ITO glass was placed in an ozone cleaner for cleaning for 30 minutes to increase the hydrophilicity of the surface. PB and pure water at 100 mg/mL were used as the plating solution, and 40 μL of the solution was evenly dripped on the surfaces of the cleaned ITO glass and the photoelectrode by spin coating at 3000 rpm for 30 seconds. Then, a cotton swab dipped in pure water was used to wipe a 1.0 cm×1.0 cm PB area on the electrode plate after the spin coating. Finally, it was placed on a hot plate at 80° C. for 30 minutes to dry to complete the preparation of the photoelectrode (WE).

2. Preparation of Counter Electrode Plate (CE): Same as Preparative Example 1.

3. Packaging of Photoelectrochromic Device: Same as Preparative Example 1.

### PREPARATIVE EXAMPLE 3

### WE is PEDOT-MeOH and CE is PB

1. Preparation of Photoelectrode (WE): Same as Preparative Example 1.

2. Preparation of Counter Electrode Plate (CE)

First, nano-Prussian blue (PB) particles were synthesized by the method of Preparative Example 2.

Then, an ITO glass was placed in an ozone cleaner for cleaning for 30 minutes to increase the hydrophilicity of the surface. PB and pure water at 100 mg/mL were used as the plating solution, and 40 μL of the solution was dripped evenly on the surface of the cleaned ITO glass by spin coating at 3000 rpm for 30 seconds. Then, a cotton swab dipped in pure water was used to wipe a 1.0 cm×1.3 cm PB area on the electrode plate after the spin coating. Finally, it was placed on a hot plate at 80° C. for 30 minutes to dry to complete the preparation of the counter electrode plate (CE).

3. Packaging of Photoelectrochromic Device: Same as Preparative Example 1.

[Response Time]

The packaged photoelectrochromic device (PECD) was fixed on the spectrophotometer platform, and the light source in the spectrophotometer was applied to the first electrochromic layer on the photoelectrode to detect the coloring/bleaching response time of the electrochromic material, and the spectrophotometer was connected with a computer to record the optical performance changes of the PECD.

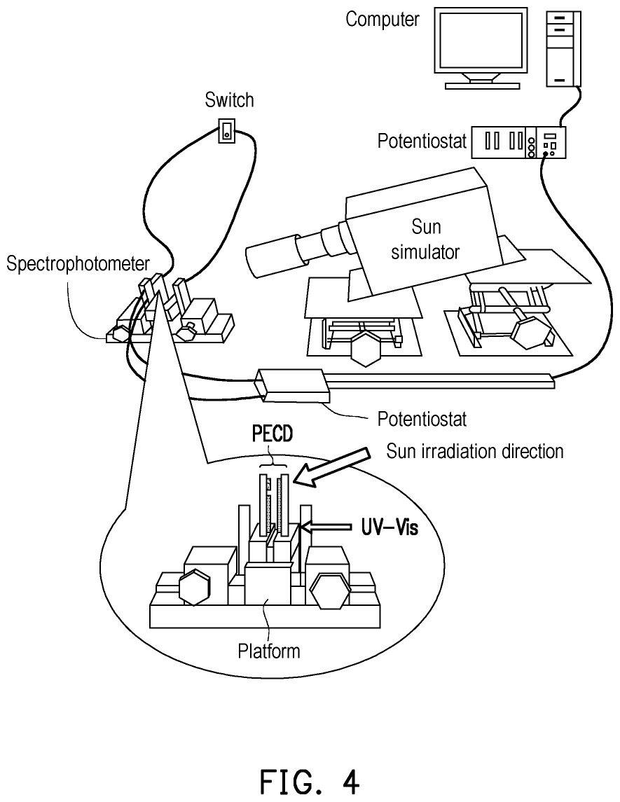

The sun simulator was set on the front-lateral side of the spectrophotometer platform to irradiate to the sensitized light-absorbing layer (TiO₂/dye layer) in the photoelectrode to drive the dye to excite electrons, so that the electrochromic material underwent a bleaching reaction. The device is as shown in FIG. 4.

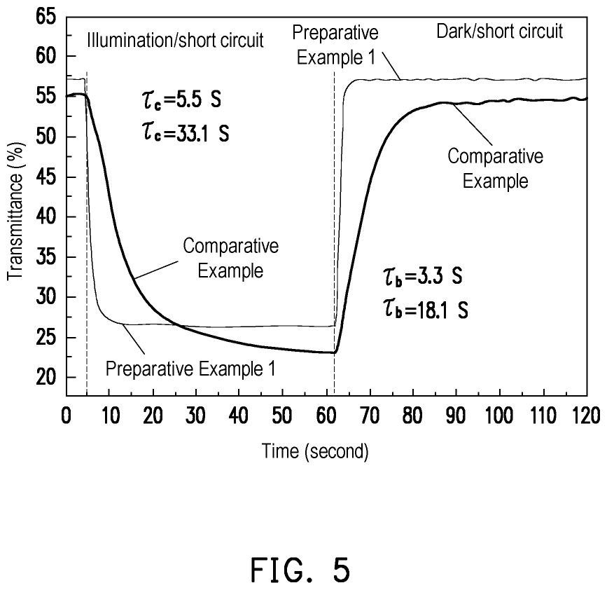

The device of FIG. 4 was used for testing, and the optical performance of Preparative Example 1 is shown in FIG. 5, where the coloring/bleaching response times are respectively τ_{c}/τ_{b}=5.5/3.3 s, and the coloring/bleaching response times of Comparative Example are respectively τ_{c}/τ_{b}=33.1/18.1 s. Therefore, the photoelectrochromic device of the disclosure has been experimentally confirmed to have a much faster response time than the conventional PECD.

[Photocoloration Efficiency]

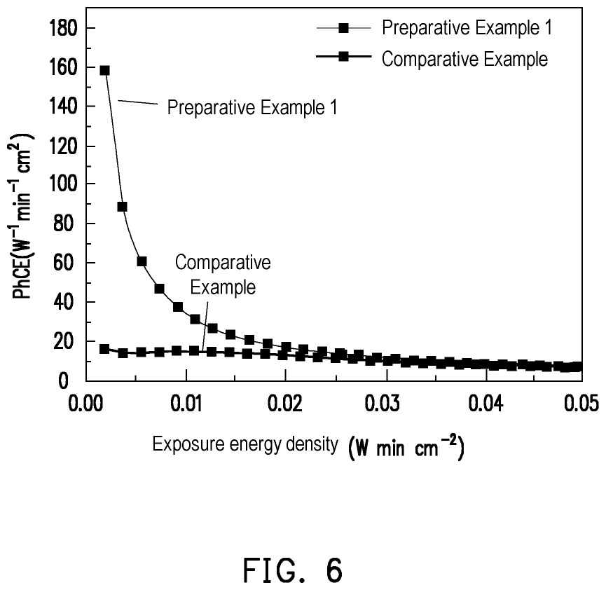

The device in FIG. 4 was similarly used to test the photocoloration efficiency, and the results are shown in FIG. 6, where the initial photocoloration efficiency of Preparative Example 1 is 160 cm² min⁻¹ W⁻¹, and the initial photocoloration efficiency of Comparative Example is about 20 cm² min⁻¹ W⁻¹. Therefore, the photoelectrochromic device of the disclosure has been experimentally confirmed to significantly improve the photocoloration efficiency.

In summary of the above, since the photoelectrode and the electrochromic layer of the disclosure can be manufactured separately, the selection of the electrochromic material can be more diverse, so as to significantly improve the slow response time of using an oxide as the electrochromic material in the conventional art. Moreover, in addition to using metal and similar materials as the counter electrode, a dual-function counter electrode having a high transmittance can also be used to enhance the performance of the PECD, so that the disclosure has a high photocoloration efficiency (PhCE) and reduced energy requirement.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A photoelectrode with independent separate structures of an electrochromic layer and a sensitized light-absorbing layer, comprising:
a first transparent conductive substrate;
a first electrochromic layer disposed on a surface of the first transparent conductive substrate; and
a sensitized light-absorbing layer disposed on the surface of the first transparent conductive substrate and adjacent to the first electrochromic layer.

2. The photoelectrode with independent separate structures of an electrochromic layer and a sensitized light-absorbing layer according to claim 1, wherein a distance between the first electrochromic layer and the sensitized light-absorbing layer is 0.05 cm or less.

3. The photoelectrode with independent separate structures of an electrochromic layer and a sensitized light-absorbing layer according to claim 1, wherein the first electrochromic layer and the sensitized light-absorbing layer are in direct contact with each other and do not overlap with each other.

4. A photoelectrochromic device comprising:
a photoelectrode, which is the photoelectrode according to claim 1, comprising the first electrochromic layer and the sensitized light-absorbing layer;
a counter electrode plate comprising a second transparent conductive substrate, and a second electrochromic layer or a metal layer disposed on a surface of the second transparent conductive substrate; and
an electrolyte located between the photoelectrode and the counter electrode plate.

5. The photoelectrochromic device according to claim 4, wherein a distance between the first electrochromic layer and the sensitized light-absorbing layer is 0.05 cm or less.

6. The photoelectrochromic device according to claim 4, wherein the first electrochromic layer and the sensitized light-absorbing layer are in direct contact with each other and do not overlap with each other.

7. The photoelectrochromic device according to claim 4, wherein a material of the first electrochromic layer and a material of the second electrochromic layer each independently comprise a transition metal oxide, a metal cyanide, an organic small molecule compound, or a conductive polymer.

8. The photoelectrochromic device according to claim 4, wherein a material of the first electrochromic layer and a material of the second electrochromic layer each independently comprise poly(3,4-ethylenedioxythiophene) (PEDOT), poly(hydroxymethyl 3,4-ethylenedioxythiophene) (PEDOT-MeOH), or Prussian blue (PB).

9. The photoelectrochromic device according to claim 4, wherein a material of the metal layer comprises platinum (Pt).

10. The photoelectrochromic device according to claim 4, wherein a ratio of an area of the first electrochromic layer to an area of the sensitized light-absorbing layer is between 1 and 4.
